(19) United States
(12) Patent Application Publication
(10) Pub. No.: US 2013/0019470 A1
(43) Pub. Date: Jan. 24, 2013

(54) METHOD OF MANUFACTURING THREE-DIMENSIONAL CIRCUIT

(71) Applicants: Chuan Ling HU, New Taipei City (TW); Yu Wei CHEN, New Taipei City (TW)

(72) Inventors: Chuan Ling HU, New Taipei City (TW); Yu Wei CHEN, New Taipei City (TW)

(73) Assignees: ICT-LANTO LIMITED, Fotan NT (HK); Chuan Ling HU, New Taipei City (TW)

(21) Appl. No.: 13/188,971

(22) Filed: Jul. 22, 2011

(51) Int. Cl. H05K 3/10

(52) U.S. Cl. 29/846

(57) ABSTRACT

A method of manufacturing 3D circuit includes the steps of providing a main body of a 3D structure; degreasing and roughening surfaces of the main body; performing a metallization process on the main body to deposit a thin metal film thereon; performing a photoresist coating process to form a photoresist protective layer on the thin metal film; performing an exposure and development process on the photoresist protective layer to form a patterned photoresist protective layer; performing an etching process to form a patterned circuit layer at areas covered by the patterned photoresist protective layer; stripping the patterned photoresist protective layer off the patterned circuit layer; and performing a chemical plating process on the patterned circuit layer to form a thickness-increased circuit layer. With the method, a 3D circuit can be formed on a 3D structure without providing additional circuit carrier to meet the requirement for miniaturized and compact electronic devices.

### FIELD OF THE INVENTION

The present invention relates to a method of manufacturing three-dimensional (3D) circuit, and more particularly to a method of forming 3D patterned metal circuit on surfaces of a main body of a 3D structure.

### BACKGROUND OF THE INVENTION

With the quick development in the wireless communication technological fields, more attention has been drawn to the requirements for signal transmission quality, compactness and low weight of all kinds of electronic communication devices. Generally, antennas for various kinds of mobile video communication products, such as tablet computers and cellular phones, have differently designed main body structures and circuit arrangements corresponding to the appearances and internal structures of the products, in order to satisfy the requirement for miniaturized communication devices.

According to a currently available forming technique, namely, laser direct structuring (LDS), a specific and laser-activatable plastic material can be injection-molded into a predetermined main body structure, and a laser beam with a specific wavelength is used to activate metal crystal grains doped in the plastic material while simultaneously defining a circuit pattern on the main body. Finally, a metallization process is performed on the main body to obtain a desired circuit. The technique of LDS is frequently applied to different products, including, but not limited to, cellular phones, antennas for mobile computers, light-emitting diode (LED) modules, in-car devices and the like.

However, the plastic material for use with LDS must be doped with a metal catalyst, and the ratio of different components of the doped metal catalyst must be changed according to the type and the material property of the plastic material used. Further, the conditions for laser activation vary with different doped metal catalysts. Therefore, in using the technique of LDS, it is necessary to adjust laser wavelength and control parameters for subsequent metallization process according to the plastic material used and the doped metal catalyst. That is, the LDS technique requires laser equipment that can provide laser beams of specific wavelengths as well as metallization equipment that can be set to different conditions or control parameters, and therefore, requires rather expensive equipment and manufacturing costs.

Moreover, in using the LDS technique, rising of main body surface temperature would cause removal or breakdown of metal crystal grains on part of the main body surfaces or even cause deposition of metal crystal grains on the main body surfaces at areas not expected for forming the circuit, resulting in reduced selectivity of deposited conducting circuit in the subsequent metallization process and accordingly, the problem of short-circuiting between adjacent electronic elements. To prevent any possible short circuit and any possible problem in the subsequent metallization process, it is necessary to control the space between circuit paths during LDS. However, large space between circuit paths would often cause another problem of insufficient circuit density.

It is therefore tried by the inventor to develop a method of manufacturing three-dimensional (3D) circuit to overcome the problems and drawbacks in the conventional techniques for forming circuits on miniaturized electronic devices.

### SUMMARY OF THE INVENTION

A primary object of the present invention is to provide a method of manufacturing three-dimensional (3D) circuit, so that a 3D circuit can be formed on a main body of any 3D structure. A metal circuit layer of the 3D circuit can be optionally formed on any one or more surfaces of the main body to achieve a patterned circuit arrangement, which can be widely applied to antennas, LED carriers, steering wheels, circuit boards, and electronic devices having differently shaped 3D structures.

Another object of the present invention is to apply a 3D circuit to a 3D antenna, so that there is high bonding force and high pull strength existed between a metal circuit layer of the 3D circuit and a main body of the antenna, allowing a signal transmission cable to be electrically connected to the antenna for receiving and transmitting signals by directly welding the cable to a feed point on the antenna.

To achieve the above and other objects, the method of manufacturing 3D circuit according to a preferred embodiment of the present invention includes the following steps: providing a main body of a 3D structure; performing a surface pretreatment on the main body; performing a metallization process on surfaces of the main body to deposit a thin metal film thereon; performing a photoresist coating process to form a photoresist protective layer on a surface of the thin metal film; performing an exposure and development process to remove part of the photoresist protective layer and expose areas of the thin metal film corresponding thereto, and form a patterned photoresist protective layer at the remained photoresist protective layer; performing an etching process on the exposed thin metal film to form a patterned circuit layer at areas covered by the patterned photoresist protective layer; performing a strip process to strip the patterned photoresist protective layer off the patterned circuit layer; and performing a chemical plating process on the patterned circuit layer to form a thickness-increased circuit layer thereat.

The main body can be a main body of an antenna, an LED carrier, a circuit substrate, a connector, an electronic device or a steering wheel respectively having a different 3D structure.

And, the main body can be made of a polymeric material or a ceramic material. The polymeric material can be polyethylene (PE), polystyrene (PS), polycarbonate (PC), acrylonitrile-butadiene-styrene (ABS), polyethylene terephthalate (PET), poly(butylenes terephthalate) (PBT), liquid crystal polymer (LCP), polyamide (PA6/6T), nylon, polyoxymethylene (POM), or any composites thereof; and the ceramic material can be aluminum oxide, zirconium dioxide, silicon nitride, silicon carbide, barium titanate, or any composites thereof. Further, the main body can be formed by injection molding or thermal sintering.

The surface pretreatment includes surface degreasing and roughening, so that the surfaces of the main body are modified into hydrophilic porous surfaces to advantageously enable an increased bonding force between the main body and the metal coating formed thereon in the subsequent step.

The metallization process includes the use of sputtering or evaporation to deposit a metal material on the surfaces of the main body to form the thin metal film; and the metal material for depositing on the main body can be nickel (Ni), cobalt (Co), palladium (Pd), Tin (Si), copper (Cu) or any composites thereof.

Alternatively, the metallization process can include sensitization using stannous ions and activation using palladium ions to activate the surfaces of the main body to form the thin metal film, so as to facilitate metal catalyst deposition in the subsequent chemical plating process.

The photoresist coating process includes dip coating or spray coating of a liquid photoresist to form the photoresist protective layer on the surface of the thin metal film; and the liquid photoresist for forming the photoresist protective layer can be a positive photoresist or a negative photoresist.

In the exposure and development process, a laser light source or an ultraviolet (UV) light source is directly irradiated on areas or positions of the photoresist protective layer defined by a specific 3D exposure circuit pattern, so that a chemical reaction occurs inside the laser-exposed or UV-exposed photoresist areas or positions. Then, a developer is used to dissolve the laser-exposed or UV-exposed photoresist areas or positions to form the patterned photoresist protective layer at the remained photoresist protective layer. And, the 3D exposure circuit pattern can be a 3D patterned mask or a directly scanned pattern.

In the chemical plating process, an electroless plating process is performed to deposit metal ions contained in an electroless plating solution on the patterned circuit layer by chemical catalysis, so as to form the thickness-increased circuit layer. The metal material for the chemical plating process can be nickel (Ni), copper (Cu), gold (Au), silver (Ag), tin (Sn), chromium (Cr) or any composites thereof.

To achieve the above and other objects, the method of manufacturing 3D circuit according to another preferred embodiment of the present invention includes the following steps: providing a main body of a 3D structure; performing a surface pretreatment on the main body; performing a photoresist coating process to form a photoresist protective layer on surfaces of the main body; performing an exposure and development process to remove part of the photoresist protective layer and form a patterned photoresist protective layer at the remained photoresist protective layer; performing a metallization process to form a patterned circuit zone on the surfaces of the main body at areas not covered by the patterned photoresist protective layer; performing a strip process to strip the patterned photoresist protective layer off the main body; and performing a chemical plating process on the patterned circuit zone to form a thickness-increased circuit layer thereat.

Similar to the previous embodiment, the main body can be a main body of an antenna, an LED carrier, a steering wheel, a circuit substrate, a connector, or an electronic device respectively having a different 3D structure. The main body can be made of a polymeric material or a ceramic material, and can be manufactured by way of injection molding or thermal sintering.

The polymeric material can be polyethylene (PE), polystyrene (PS), polycarbonate (PC), acrylonitrile-butadiene-styrene (ABS), polyethylene terephthalate (PET), poly(butylenes terephthalate) (PBT), liquid crystal polymer (LCP), polyamide (PA6/6T), nylon, polyoxymethylene (POM), or any composites thereof; and the ceramic material can be aluminum oxide, zirconium dioxide, silicon nitride, silicon carbide, barium titanate, or any composites thereof.

The surface pretreatment includes surface degreasing and roughening, so that the surfaces of the main body are modified into hydrophilic porous surfaces to advantageously enable an increased bonding force between the main body and the metal coating formed thereon in the subsequent step.

The photoresist coating process includes dip coating or spray coating of a liquid photoresist to form the photoresist protective layer on the surfaces of the main body; and the liquid photoresist for forming the photoresist protective layer can be a positive photoresist or a negative photoresist.

In the exposure and development process, a laser light source or an ultraviolet (UV) light source is directly irradiated on areas or positions of the photoresist protective layer defined by a specific 3D exposure circuit pattern, so that a chemical reaction occurs inside the laser-exposed or UV-exposed photoresist areas or positions. Then, a developer is used to dissolve the laser-exposed or UV-exposed photoresist areas or positions to expose surfaces of the main body corresponding thereto and to form the patterned photoresist protective layer at the remained photoresist coating. The subsequent metallization process is performed on the exposed main body surfaces to form the patterned circuit zone. And, the 3D exposure circuit pattern can be a 3D patterned mask or a directly scanned pattern.

The metallization process includes the use of sputtering or evaporation to deposit a metal material on the surfaces of the main body to form the patterned circuit zone; and the metal material for depositing on the main body can be nickel (Ni), cobalt (Co), palladium (Pd), Tin (Si), copper (Cu) or any composites thereof. Alternatively, the metallization process can include sensitization using stannous ions and activation using palladium ions to activate the surfaces of the main body to form the patterned circuit zone, so as to facilitate metal catalyst deposition in the subsequent chemical plating process.

In the chemical plating process, an electroless plating process is performed to deposit metal ions contained in an electroless plating solution on the patterned circuit zone by chemical catalysis, so as to form the thickness-increased circuit layer. The metal material for the chemical plating process can be nickel (Ni), copper (Cu), gold (Au), silver (Ag), tin (Sn), chromium (Cr) or any composites thereof.

With the method of manufacturing 3D circuit according to the embodiments of the present invention, the following advantages can be obtained:

(1) The main body can be made of a general plastic material without the need of using a specific material having a doped metal catalyst. Therefore, a wide range of plastic materials can be considered for use to enable reduced material cost.

(2) The manufactured 3D circuit has good size-precision and circuit density to maintain stable antenna impedance match.

(3) A 3D circuit with complicated circuit pattern can be flexibly manufactured at reduced time and cost without being limited by mold geometry, machining equipment or complicated circuit structure as in the conventional circuit forming techniques.

(4) The metal circuit is integrally formed on the main body, and there is high bonding strength existed between them to save the procedures of assembling independently manufactured plastic antenna main body and metal conducting plate to one another, and to eliminate the problems of separated metal conducting plate and plastic main body due to assembling error or collision.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a flowchart showing the steps included in a method according to a first embodiment of the present invention for manufacturing a 3D antenna circuit;

FIGS. 2 to 4 illustrate the manufacture of a 3D antenna circuit according to the method of FIG. 1;

FIG. 5 is a flowchart showing the steps included in a method according to a second embodiment of the present invention for manufacturing a 3D antenna circuit;

FIGS. 6 to 8 illustrate the manufacture of a 3D antenna circuit according to the method of FIG. 5;

FIG. 9 shows the connection of a signal transmission cable to the 3D antenna circuit formed on a 3D antenna main body according to the method of the present invention;

FIGS. 10 to 13 illustrate the manufacture of a 3D LED carrier circuit using a method according to a third embodiment of the present invention;

FIGS. 14 to 17 illustrate the manufacture of a 3D LED carrier circuit using a method according to a fourth embodiment of the present invention;

FIGS. 18 to 21 illustrate the manufacture of a 3D steering wheel circuit using a method according to a fifth embodiment of the present invention; and

FIGS. 22 to 25 illustrate the manufacture of a 3D steering wheel circuit using a method according to a sixth embodiment of the present invention.

### DETAILED DESCRIPTION OF THE PREFERRED EMBODIMENTS

The present invention will now be described with some preferred embodiments thereof and with reference to the accompanying drawings. For the purpose of easy to understand, elements that are the same in the preferred embodiments are denoted by the same reference numerals.

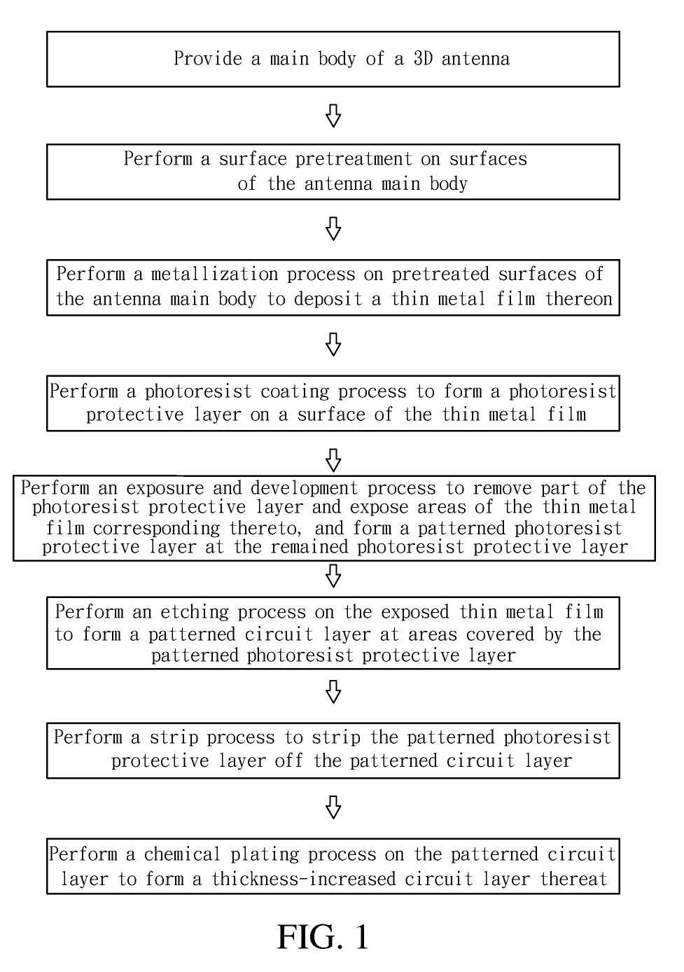

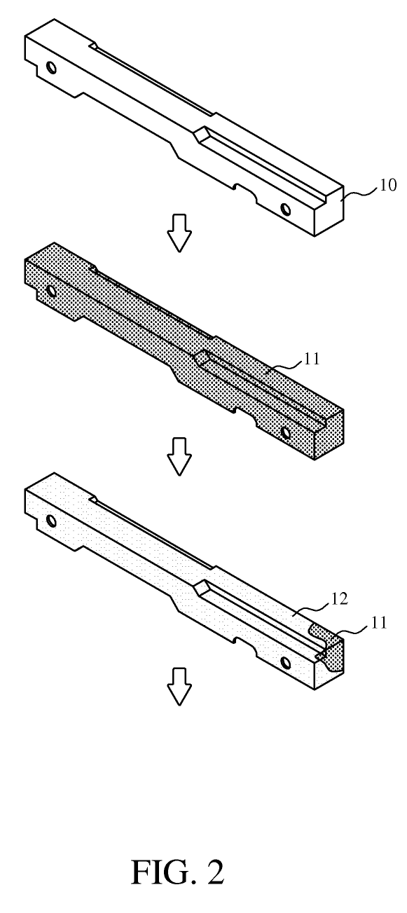

FIG. 1 is a flowchart showing the steps included in a method according to a first embodiment of the present invention for manufacturing a 3D antenna circuit. Please refer to FIG. 1 along with FIGS. 2 to 4, in which the steps of forming the 3D antenna circuit according to the method of FIG. 1 are correspondingly illustrated.

In a first step, a main body 10 of a 3D antenna is provided, as shown in FIG. 2.

In a second step, a surface pretreatment is performed on surfaces of the antenna main body 10.

In a third step, a metallization process is performed, so that a thin metal film 11 is deposited on the pretreated surfaces of the antenna main body 10, as shown in FIG. 2.

In a fourth step, a photoresist coating process is performed, so that a photoresist protective layer 12 is formed on the surface of the thin metal film 11, as shown in FIG. 2.

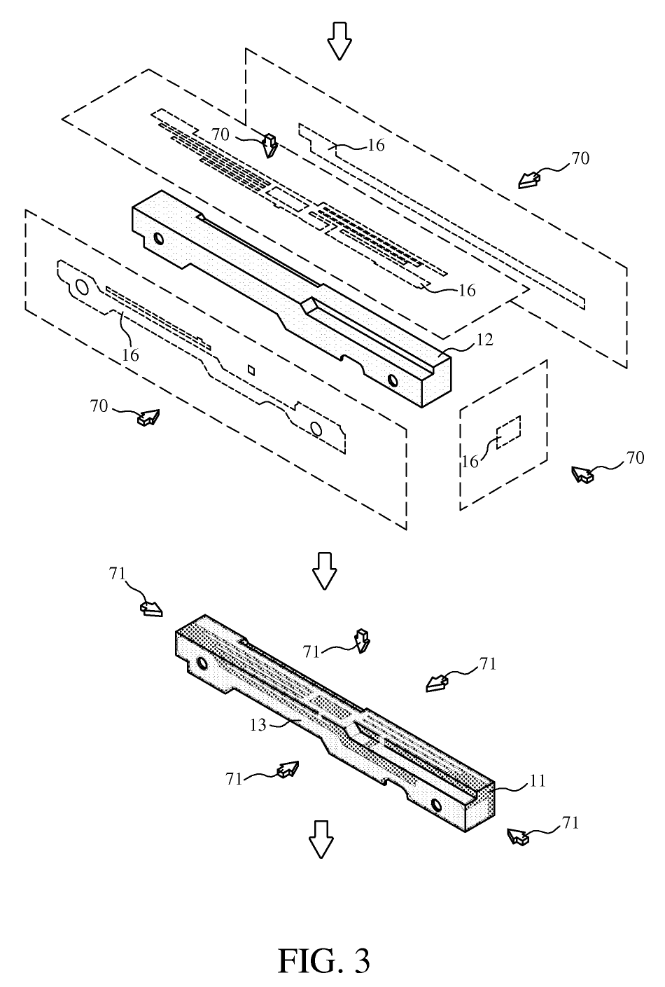

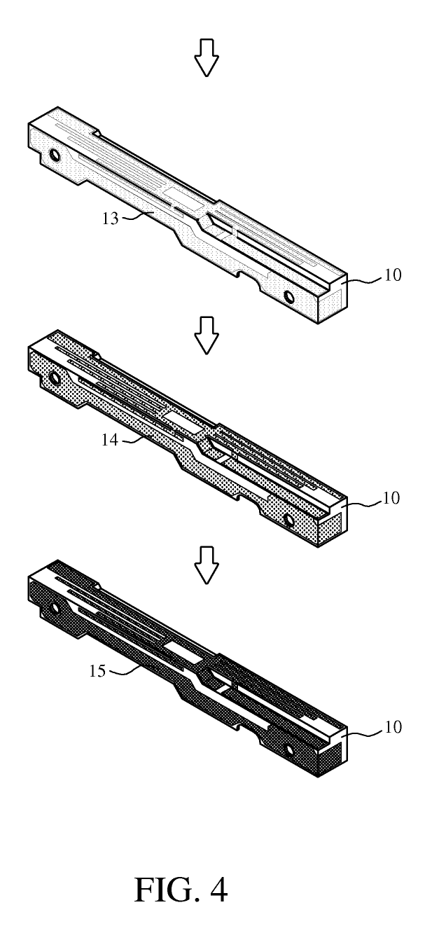

In a fifth step, an exposure and development process 70 is performed, so that part of the photoresist protective layer 12 is removed to expose areas of the thin metal film 11 corresponding thereto, and the remained photoresist protective layer 12 forms a patterned photoresist protective layer 13, as shown in FIGS. 3 and 4.

In a sixth step, an etching process 71 is performed on the exposed thin metal film 11, as shown in FIG. 3, so that a patterned circuit layer 14 is formed at areas being covered by the patterned photoresist protective layer 13, as shown in FIG. 4.

In a seventh step, a strip process is performed to strip the patterned photoresist protective layer 13 off the patterned circuit layer 14, as shown in FIG. 4.

And, in an eighth step, a chemical plating process is performed on the patterned circuit layer 14 to form a thickness-increased circuit layer 15, as shown in FIG. 4.

More specifically, in the above first step, the provided main body 10 of the 3D antenna is manufactured by way of injection molding or thermal sintering. The antenna main body 10 may be made of a polymeric material or a ceramic material.

The polymeric material can be polyethylene (PE), polystyrene (PS), polycarbonate (PC), acrylonitrile-butadiene-styrene (ABS), polyethylene terephthalate (PET), poly(butylenes terephthalate) (PBT), liquid crystal polymer (LCP), polyamide (PA6/6T), nylon, polyoxymethylene (POM) or any composites thereof. The ceramic material can be aluminum oxide, zirconium dioxide, silicon nitride, silicon carbide, barium titanate or any composites thereof.

In the above second step, the surface pretreatment includes surface degreasing and surface roughening. More specifically, an acid or alkaline cleaning agent is used to remove dirt and grease from the surfaces of the antenna main body 10, and mechanical abrasion, chemical etching or plasma etching is used to roughen the degreased surfaces of the antenna main body 10, so that the surfaces of the antenna main body 10 are modified into hydrophilic porous surfaces, which advantageously enables an increased bonding force between the antenna main body 10 and the metal coating formed thereon in the subsequent step.

In the above third step, the metallization process includes the use of sputtering or evaporation to deposit a metal material on the surfaces of the antenna main body 10 to form the thin metal film 11. And, the depositing metal can be nickel (Ni), cobalt (Co), palladium (Pd), Tin (Si), copper (Cu) or any composites thereof.

Alternatively, in the above third step, the metallization process may include sensitization using stannous ions and activation using palladium ions, so that the surfaces of the antenna main body 10 are activated to form the thin metal film 11. In the sensitization process, stannous chloride mixes with stannous ions (Sn₂⁺) contained in an acid solution and then permeates into pores on the pretreated surfaces of the antenna main body 10 to thereby adsorb on the surfaces of the antenna main body 10; and in the activation process, palladium chloride mixes with palladium ions (Pd₂) contained in an acid solution and then forms active metal particles in an implantation reaction, so as to facilitate metal catalyst deposition in the subsequent chemical plating process.

In the above fourth step, the photoresist coating process includes dip coating or spray coating of a liquid photoresist to form the photoresist protective layer 12 on the surface of the thin metal film 11. And, the liquid photoresist for forming the photoresist protective layer 12 can be a positive or a negative photoresist.

In the above fifth step, the exposure and development process 70 includes the irradiation of a laser light source or an ultraviolet (UV) light source directly on areas or positions of the photoresist protective layer 12 defined by a specific 3D exposure circuit pattern 16, as shown in FIG. 3, so that a chemical reaction occurs inside the laser-exposed or UV-exposed photoresist areas or positions. Then, a developer is used to dissolve the laser-exposed or UV-exposed photoresist areas or positions to form the patterned photoresist protective layer 13 at the remained photoresist coating.

In a preferred embodiment of the present invention, the 3D exposure circuit pattern 16 can be a 3D patterned mask or a directly scanned pattern.

In the above sixth step, the etching process 71 includes the use of a chemical etching solution to etch away the exposed thin metal film 11 that is no longer protected by the photoresist after the fifth step, so as to form the patterned circuit layer 14 below the patterned photoresist protective layer 13.

In the above seventh step, the strip process includes the use of an organic solvent to remove the patterned photoresist protective layer 13 from the antenna main body 10 so as to expose the patterned circuit layer 14, on which the subsequent chemical plating process is performed.

In the above eighth step, the chemical plating process includes the use of electroless plating process to deposit metal ions contained in an electroless plating solution on the patterned circuit layer 14 by chemical catalysis, so as to form the thickness-increased circuit layer 15. The metal material used in the chemical plating process can be nickel (Ni), copper (Cu), gold (Au), silver (Ag), tin (Sn), chromium (Cr) or any composites thereof.

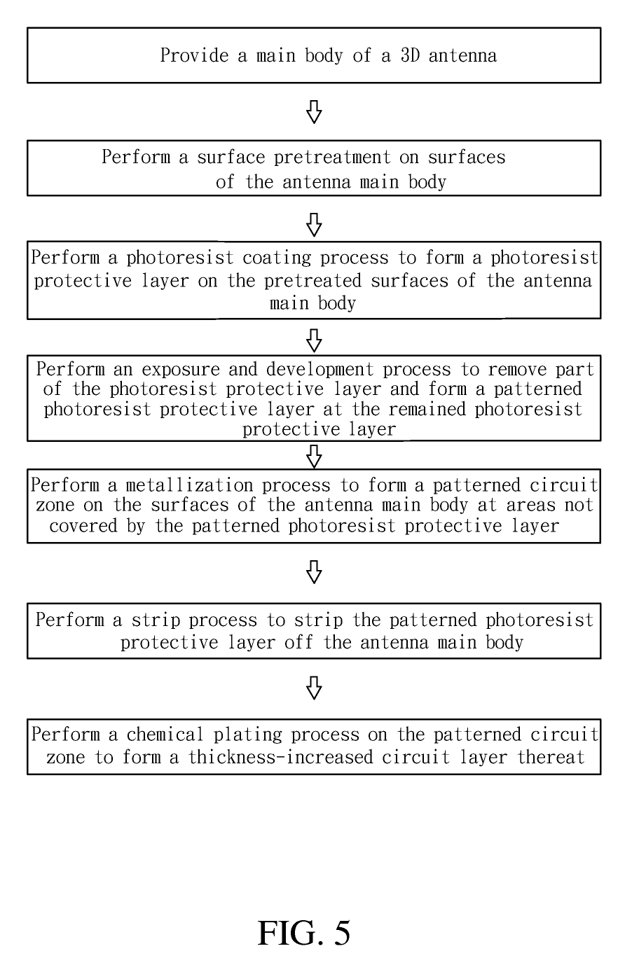

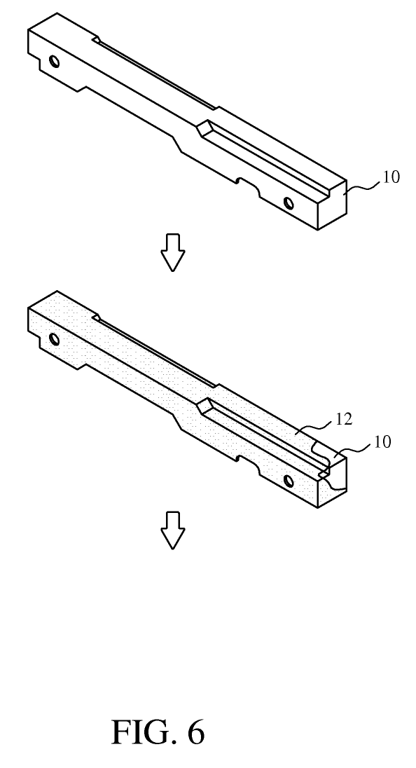

FIG. 5 is a flowchart showing the steps included in a method according to a second embodiment of the present invention for manufacturing a 3D antenna circuit. Please refer to FIG. 5 along with FIGS. 6 to 8, in which the steps of forming the 3D antenna circuit according to the method of FIG. 5 are correspondingly illustrated.

In a first step, a main body 10 of a 3D antenna is provided, as shown in FIG. 6.

In a second step, a surface pretreatment is performed on surfaces of the antenna main body 10.

In a third step, a photoresist coating process is performed, so that a photoresist protective layer 12 is formed on the surfaces of the antenna main body 10, as shown in FIG. 6.

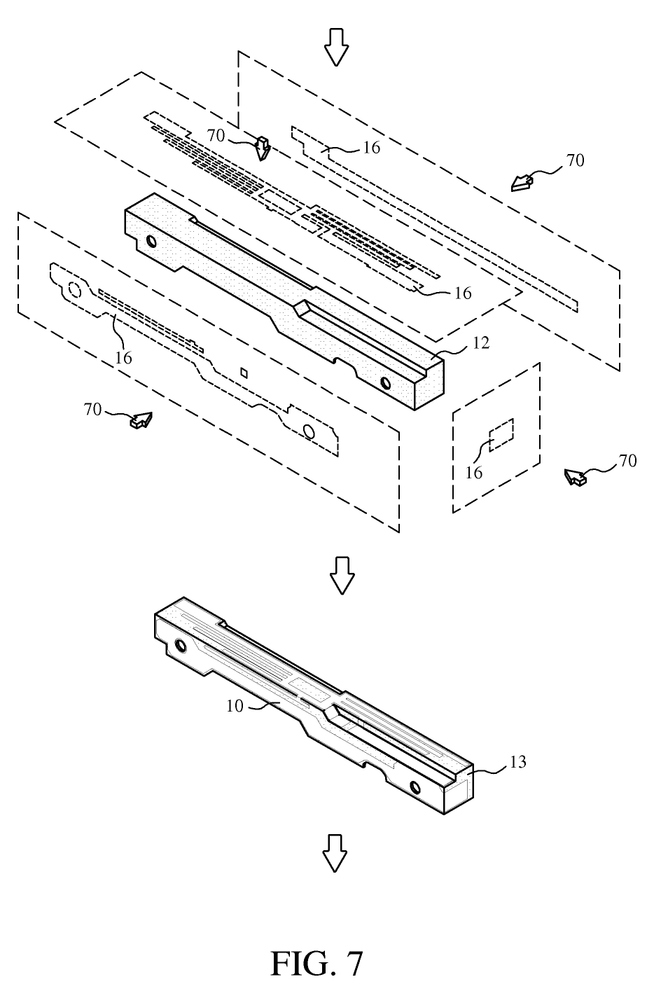

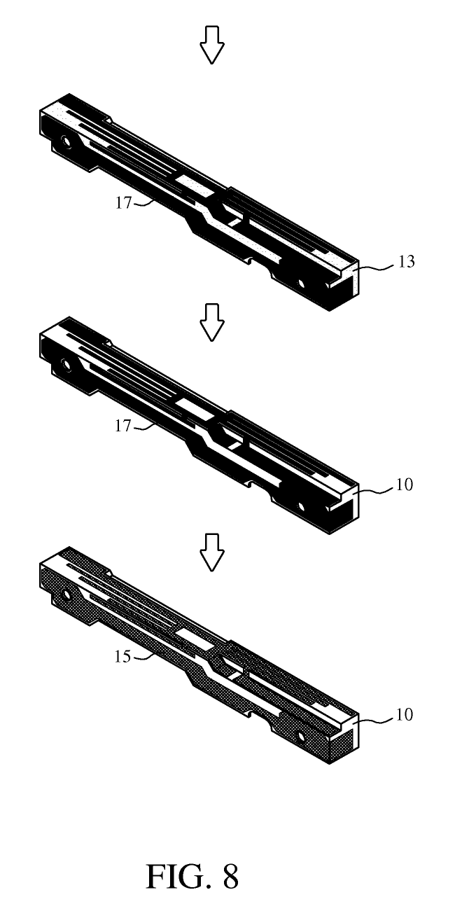

In a fourth step, an exposure and development process 70 is performed, so that part of the photoresist protective layer 12 is removed and the remained photoresist protective layer 12 forms a patterned photoresist protective layer 13, as shown in FIGS. 7 and 8.

In a fifth step, a metallization process is performed, so that a patterned circuit zone 17 is formed on the surfaces of the antenna main body 10 at areas not covered by the patterned photoresist protective layer 13, as shown in FIG. 8.

In a sixth step, a strip process is performed to strip the patterned photoresist protective layer 13 off the antenna main body 10, as shown in FIG. 8.

And, in a seventh step, a chemical plating process is performed on the patterned circuit zone 17 to form a thickness-increased circuit layer 15 thereat, as shown in FIG. 8.

In the above first step, since the ways and the materials that can be used to form the antenna main body 10 are the same as those in the first embodiment, they are not repeatedly described in details herein.

In the above second step, the surface pretreatment is the same as that in the first embodiment and is therefore not repeatedly described herein.

In the above third step, the photoresist coating process includes dip coating or spray coating of a liquid photoresist to form the photoresist protective layer 12 on the surfaces of the antenna main body 10. And, the liquid photoresist for forming the photoresist protective layer 12 can be a positive or a negative photoresist.

In the above fourth step, the exposure and development process 70 includes the irradiation of a laser light source or an ultraviolet (UV) light source directly on areas or positions of the photoresist protective layer 12 defined by a specific 3D exposure circuit pattern 16, as shown in FIG. 7, so that a chemical reaction occurs inside the laser-exposed or UV-exposed photoresist areas or positions. Then, a developer is used to dissolve the laser-exposed or UV-exposed photoresist areas or positions, so that surfaces of the antenna main body 10 corresponding thereto are exposed, and the patterned photoresist protective layer 13 is formed at the remained photoresist coating. The exposed surfaces of the antenna main body 10 will then be used to form the patterned circuit zone 17 in the subsequent metallization process in the fifth step.

In a preferred embodiment of the present invention, the 3D exposure circuit pattern 16 can be a 3D patterned mask or a directly scanned pattern.

In the above fifth step, the metallization process includes the use of sputtering or evaporation to deposit a metal material on the surfaces of the antenna main body 10 to form the patterned circuit zone 17. And, the depositing metal can be nickel (Ni), cobalt (Co), palladium (Pd), Tin (Si), copper (Cu), or any composites thereof.

Alternatively, in the above fifth step, the metallization process may include sensitization using stannous ions and activation using palladium ions, so that the surfaces of the antenna main body 10 are activated to form the patterned circuit zone 17. In the sensitization process, stannous chloride mixes with stannous ions (Sn₂⁺) contained in an acid solution and then permeates into pores on the pretreated surfaces of the antenna main body 10 to thereby adsorb on the surfaces of the antenna main body 10; and in the activation process, palladium chloride mixes with palladium ions (Pd₂) contained in an acid solution and then forms active metal particles in an implantation reaction, so as to facilitate metal catalyst deposition in the subsequent chemical plating process.

In the above sixth step, the strip process includes the use of an organic solvent to remove the patterned photoresist protective layer 13 from the surfaces of the antenna main body 10. Meanwhile, the metal deposition on the surface of the patterned photoresist protective layer 13 is also removed.

In the above seventh step, the chemical plating process includes the use of electroless plating process to deposit metal ions contained in an electroless plating solution on the activated patterned circuit zone 17 by chemical catalysis, so as to form the thickness-increased circuit layer 15. The metal material used in the chemical plating process can be nickel (Ni), copper (Cu), gold (Au), silver (Ag), tin (Sn), chromium (Cr) or any composites thereof.

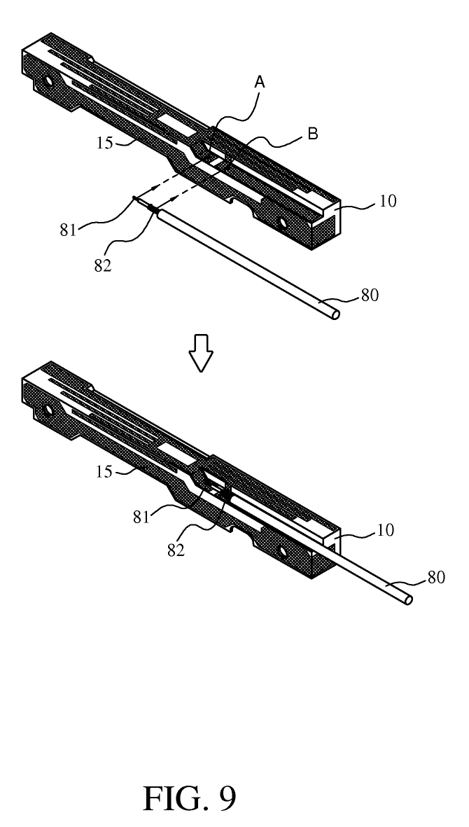

FIG. 9 shows the connection of a signal transmission cable 80 to the thickness-increased circuit layer 15 formed on a 3D antenna main body 10 according to the method of the present invention. As shown, the antenna main body 10 has a signal transmission cable 80 connected thereto. The signal transmission cable 80 internally includes a center conductor 81 and a grounding conductor 82. The center conductor 81 and the grounding conductor 82 are connected to a feed point A and a grounding point B, respectively, on the thickness-increased circuit layer 15, so that an antenna assembly for transmitting or receiving wireless signals is formed and can be mounted on a mobile computer or other types of wireless communication devices.

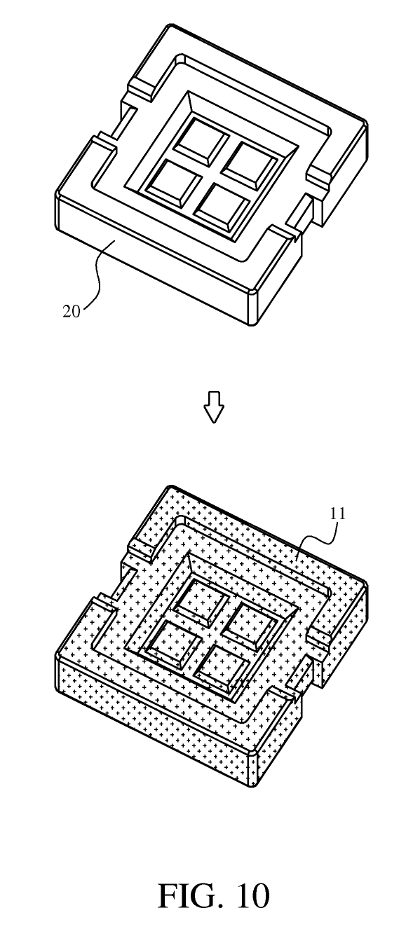

Please now refer to FIGS. 10 to 13 that illustrate the steps included in a method according to a third preferred embodiment of the present invention for manufacturing a 3D LED carrier circuit.

In a first step of the method according to the third preferred embodiment of the present invention, a main body 20 of an LED carrier having a 3D structure is provided, as shown in FIG. 10.

In a second step, a surface pretreatment is performed on surfaces of the LED carrier main body 20.

In a third step, a metallization process is performed, so that a thin metal film 11 is deposited on the pretreated surfaces of the LED carrier main body 20, as shown in FIG. 10.

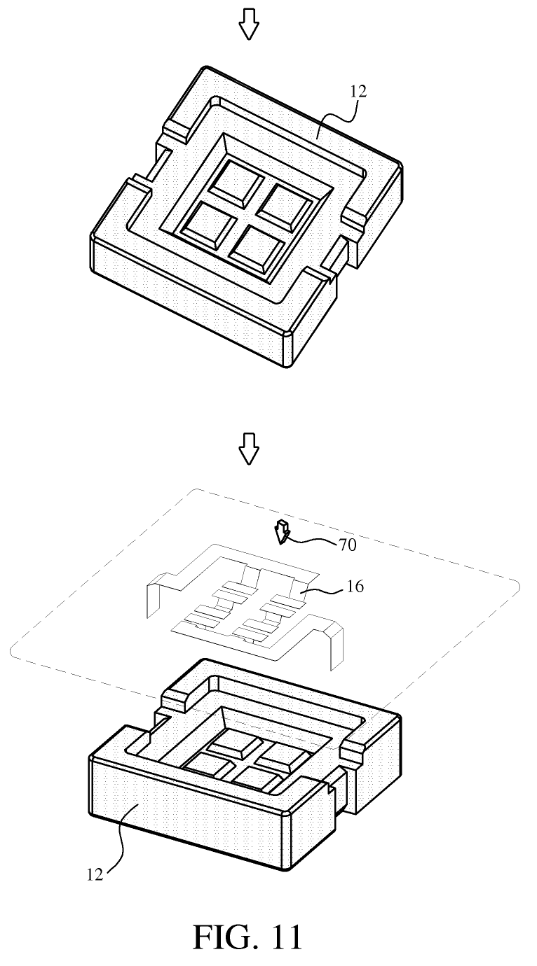

In a fourth step, a photoresist coating process is performed, so that a photoresist protective layer 12 is formed on the surface of the thin metal film 11, as shown in FIG. 11.

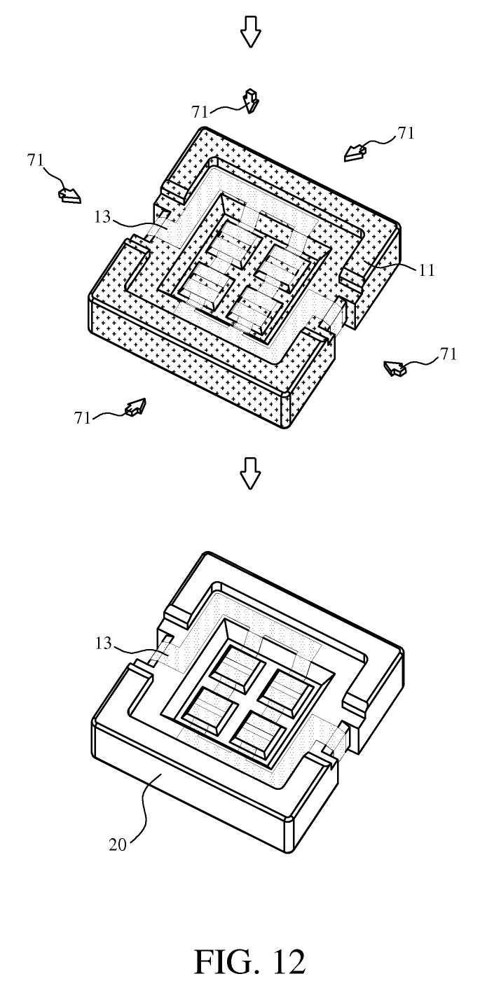

In a fifth step, an exposure and development process 70 is performed, so that part of the photoresist protective layer 12 is removed to expose areas of the thin metal film 11 corresponding thereto, and the remained photoresist protective layer 12 forms a patterned photoresist protective layer 13, as shown in FIGS. 11 and 12.

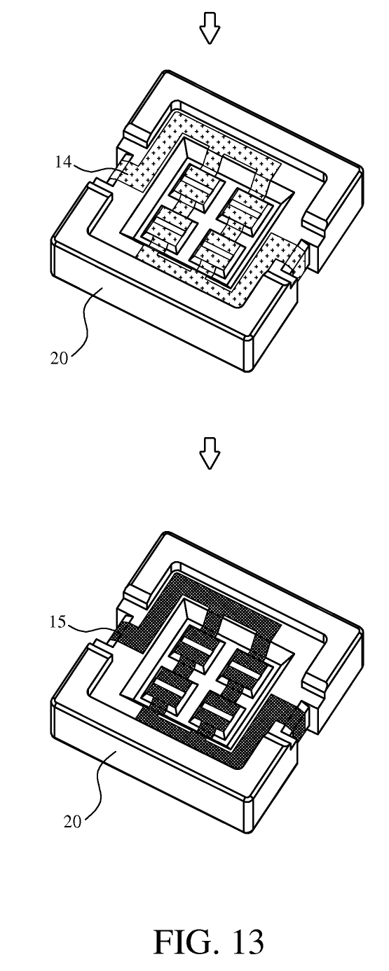

In a sixth step, an etching process 71 is performed on the exposed thin metal film 11, as shown in FIG. 12, so that a patterned circuit layer 14 is formed at areas being covered by the patterned photoresist protective layer 13, as shown in FIG. 13.

In a seventh step, a strip process is performed to strip the patterned photoresist protective layer 13 off the patterned circuit layer 14, as shown in FIG. 13.

And, in an eighth step, a chemical plating process is performed on the patterned circuit layer 14 to form a thickness-increased circuit layer 15, as shown in FIG. 13.

Since the above second to eighth steps in the third preferred embodiment are similar to the second to eighth steps in the first preferred embodiment, they are not repeatedly described in details herein.

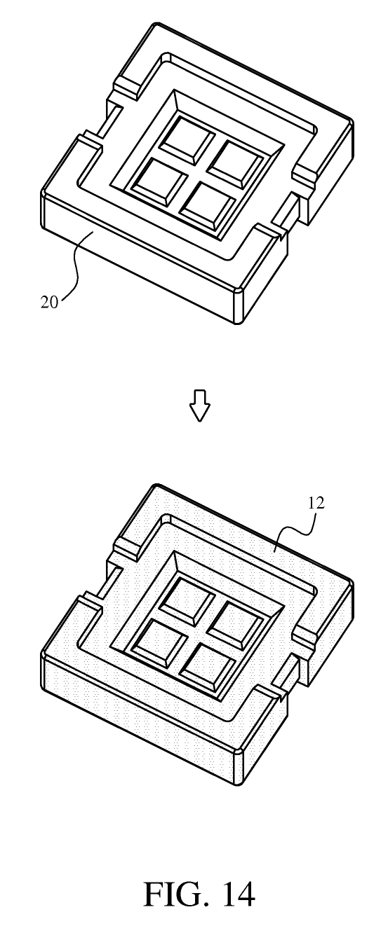

Please refer to FIGS. 14 to 17 that illustrate the steps included in a method according to a fourth preferred embodiment of the present invention for manufacturing a 3D LED carrier circuit.

In a first step of the method according to the fourth preferred embodiment of the present invention, a main body 20 of an LED carrier having a 3D structure is provided, as shown in FIG. 14.

In a second step, a surface pretreatment is performed on surfaces of the LED carrier main body 20.

In a third step, a photoresist coating process is performed, so that a photoresist protective layer 12 is formed on the surfaces of the LED carrier main body 20, as shown in FIG. 14.

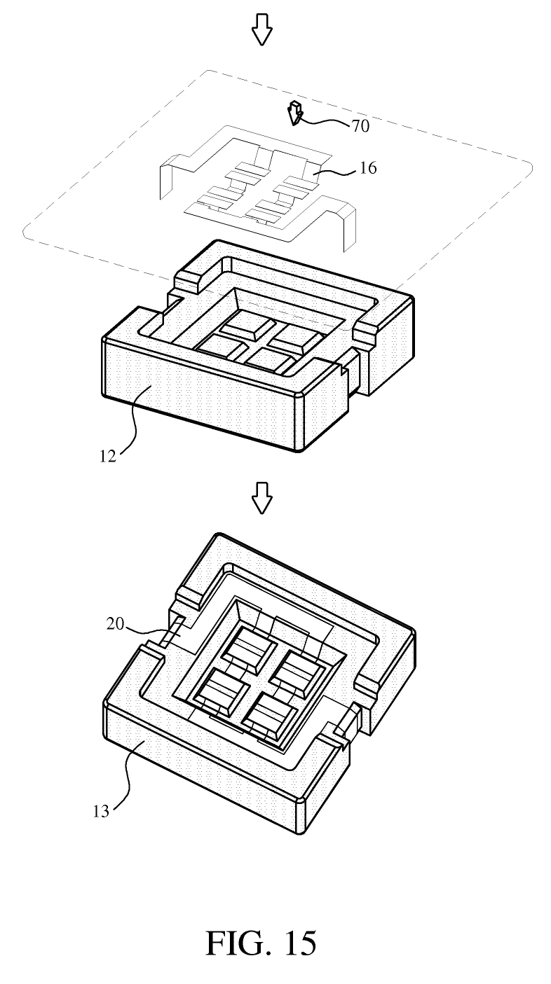

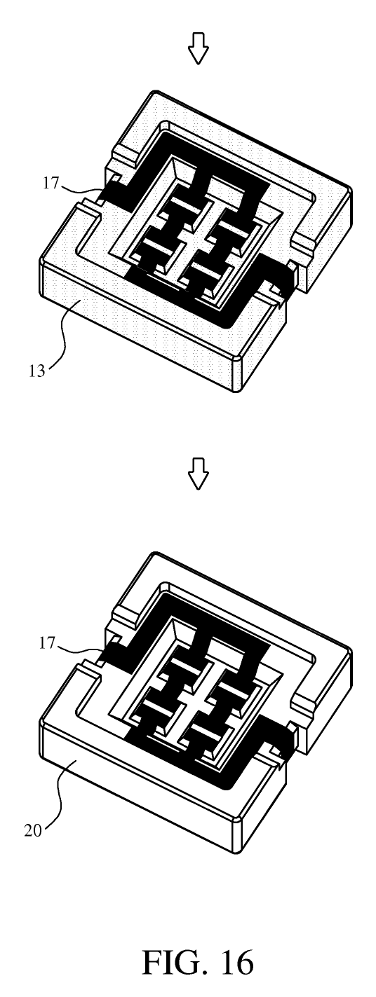

In a fourth step, an exposure and development process 70 is performed, so that part of the photoresist protective layer 12 is removed and the remained photoresist protective layer 12 forms a patterned photoresist protective layer 13, as shown in FIGS. 15 and 16.

In a fifth step, a metallization process is performed, so that a patterned circuit zone 17 is formed on the surfaces of the LED carrier main body 20 at areas not covered by the patterned photoresist protective layer 13, as shown in FIG. 16.

In a sixth step, a strip process is performed to strip the patterned photoresist protective layer 13 off the LED carrier main body 20, as shown in FIG. 16.

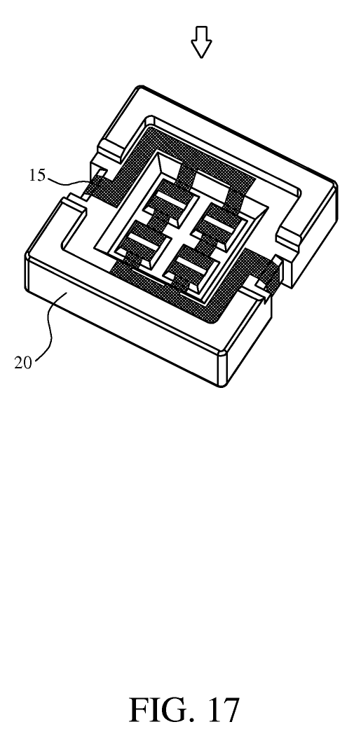

And, in a seventh step, a chemical plating process is performed on the patterned circuit zone 17 to form a thickness-increased circuit layer 15 thereat, as shown in FIG. 17.

Since the above second to seventh steps in the fourth preferred embodiment are similar to the second to seventh steps in the second preferred embodiment, they are not repeatedly described in details herein.

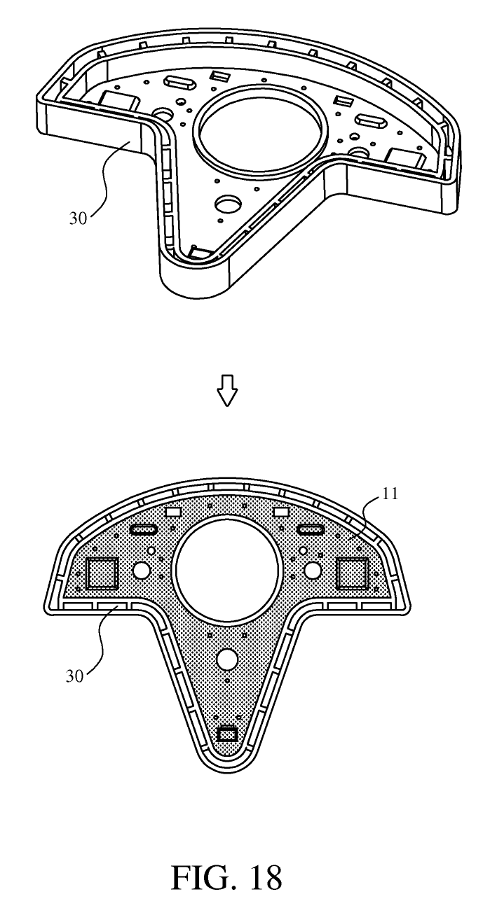

Please now refer to FIGS. 18 to 21 that illustrate the steps included in a method according to a fifth preferred embodiment of the present invention for manufacturing a 3D steering wheel circuit.

In a first step of the method according to the fifth preferred embodiment of the present invention, a main body 30 of a steering wheel having a 3D structure is provided, as shown in FIG. 18.

In a second step, a surface pretreatment is performed on surfaces of the steering wheel main body 30.

In a third step, a metallization process is performed, so that a thin metal film 11 is deposited on the pretreated surfaces of the steering wheel main body 30, as shown in FIG. 18.

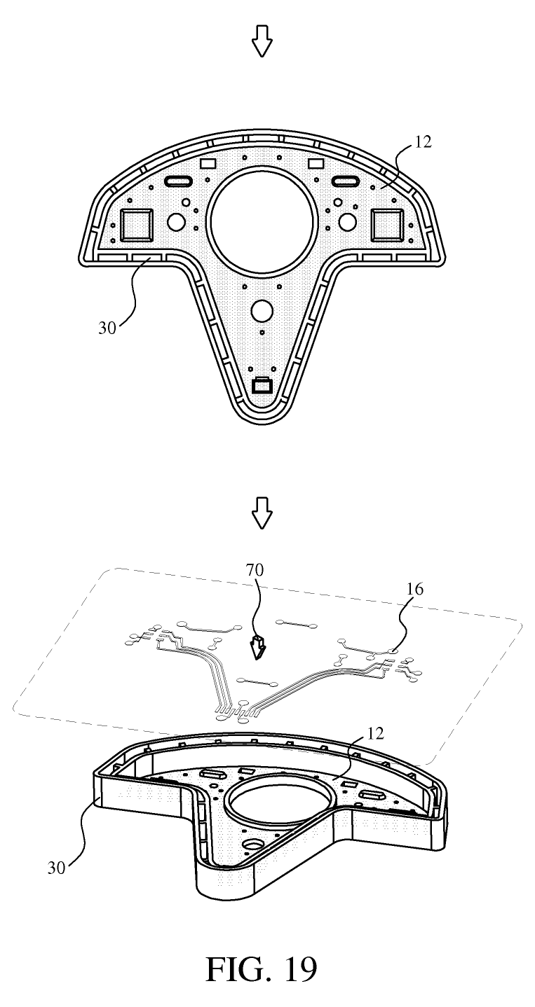

In a fourth step, a photoresist coating process is performed, so that a photoresist protective layer 12 is formed on the surface of the thin metal film 11, as shown in FIG. 19.

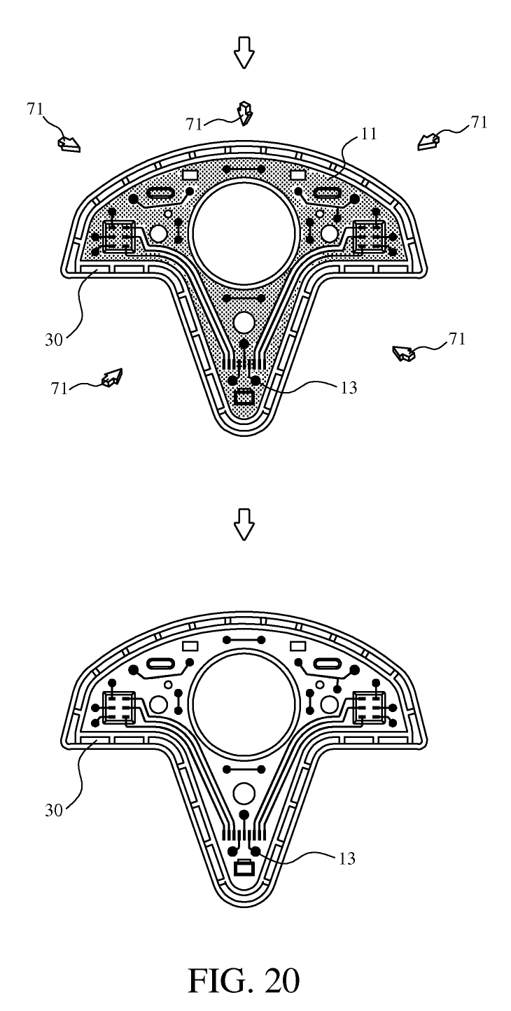

In a fifth step, an exposure and development process 70 is performed, so that part of the photoresist protective layer 12 is removed to expose areas of the thin metal film 11 corresponding thereto, and the remained photoresist protective layer 12 forms a patterned photoresist protective layer 13, as shown in FIGS. 19 and 20.

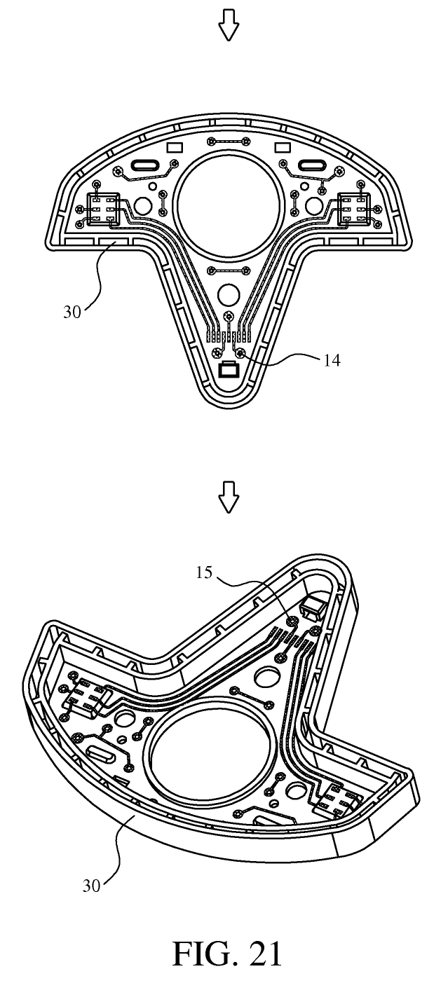

In a sixth step, an etching process 71 is performed on the exposed thin metal film 11, as shown in FIG. 20, so that a patterned circuit layer 14 is formed at areas being covered by the patterned photoresist protective layer 13, as shown in FIG. 21.

In a seventh step, a strip process is performed to strip the patterned photoresist protective layer 13 off the patterned circuit layer 14, as shown in FIG. 21.

And, in an eighth step, a chemical plating process is performed on the patterned circuit layer 14 to form a thickness-increased circuit layer 15 thereat, as shown in FIG. 21.

Since the above second to eighth steps in the fifth preferred embodiment are similar to the second to eighth steps in the first preferred embodiment, they are not repeatedly described in details herein.

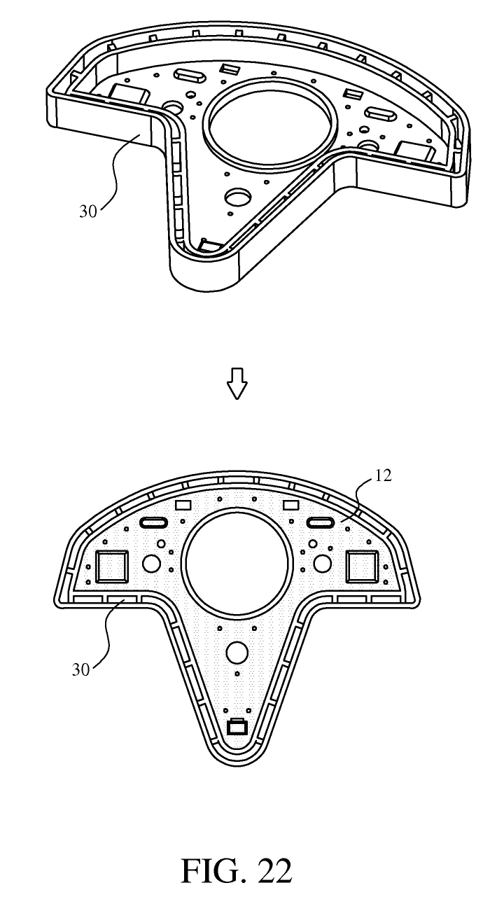

Please refer to FIGS. 22 to 25 that illustrate the steps included in a method according to a sixth preferred embodiment of the present invention for manufacturing a 3D steering wheel circuit.

In a first step of the method according to the sixth preferred embodiment of the present invention, a main body 30 of a steering wheel having a 3D structure is provided, as shown in FIG. 22.

In a second step, a surface pretreatment is performed on surfaces of the steering wheel main body 30.

In a third step, a photoresist coating process is performed, so that a photoresist protective layer 12 is formed on the surfaces of the steering wheel main body 30, as shown in FIG. 22.

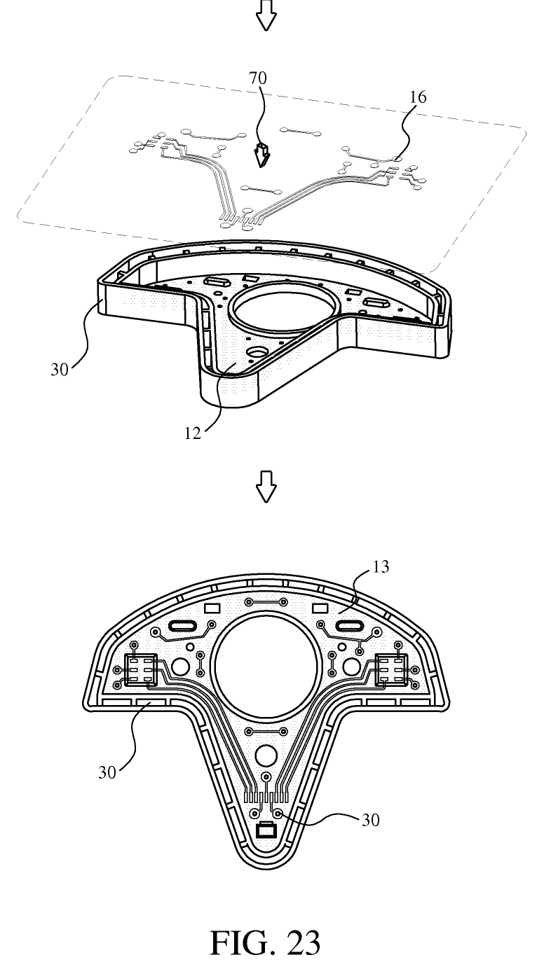

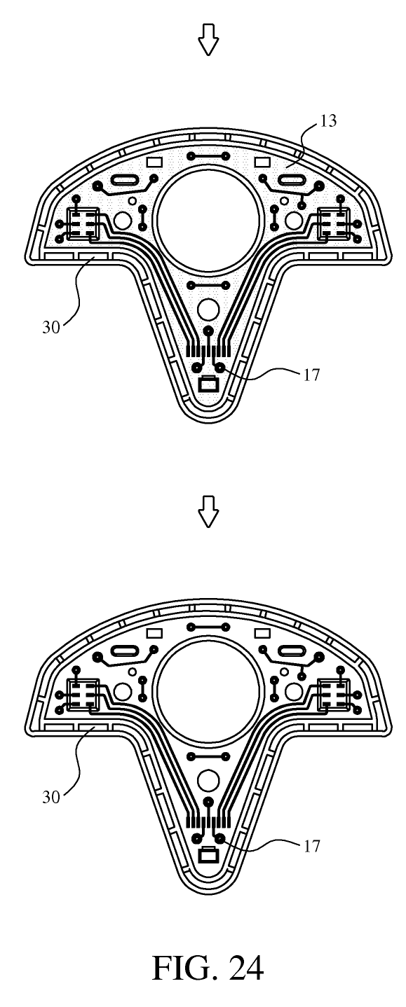

In a fourth step, an exposure and development process 70 is performed, so that part of the photoresist protective layer 12 is removed and the remained photoresist protective layer 12 forms a patterned photoresist protective layer 13, as shown in FIGS. 23 and 24.

In a fifth step, a metallization process is performed, so that a patterned circuit zone 17 is formed on the surfaces of the steering wheel main body 30 at areas not covered by the patterned photoresist protective layer 13, as shown in FIG. 24.

In a sixth step, a strip process is performed to strip the patterned photoresist protective layer 13 off the steering wheel main body 30, as shown in FIG. 24.

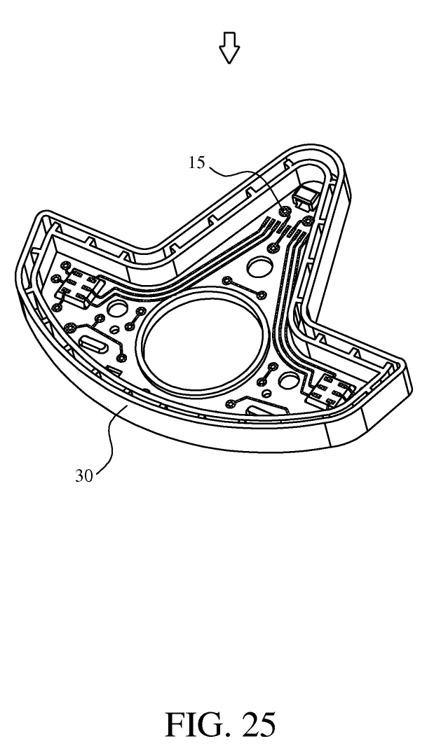

And, in a seventh step, a chemical plating process is performed on the patterned circuit zone 17 to form a thickness-increased circuit layer 15 thereat, as shown in FIG. 25.

Since the above second to seventh steps in the sixth preferred embodiment are similar to the second to seventh steps in the second preferred embodiment, they are not repeatedly described in details herein.

As can be found from the above illustrated six preferred embodiments, the method of manufacturing 3D circuit according to the present invention is applicable to various kinds of differently shaped 3D structures, including, but not limited to, antennas,

LED carriers, steering wheels, circuit boards, connectors and electronic devices, to save the spaces needed by the main bodies of these 3D structures. In conclusion, with the method of manufacturing 3D circuit according to the present invention, a 3D circuit can be formed on any 3D object's main body. The metal circuit layer of the 3D circuit can be optionally formed on any one or more surfaces of the 3D main body to achieve a patterned circuit arrangement, which can be widely applied to antennas, LED carriers, steering wheels, circuit boards, and electronic devices having differently shaped 3D structures without the need of providing additional circuit carriers inside the main bodies thereof. Therefore, the main bodies of these devices can have largely reduced volume to meet the requirement for using in miniaturized, compact and low weight electronic devices.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A method of manufacturing 3D circuit, comprising the following steps:
providing a main body of a 3D structure;
performing a surface pretreatment on surfaces of the main body;
performing a metallization process on pretreated surfaces of the main body to deposit a thin metal film thereon;
performing a photoresist coating process to form a photoresist protective layer on a surface of the thin metal film;
performing an exposure and development process to remove part of the photoresist protective layer and expose areas of the thin metal film corresponding thereto, and form a patterned photoresist protective layer at the remained photoresist protective layer;
performing an etching process on the exposed thin metal film to form a patterned circuit layer at areas covered by the patterned photoresist protective layer;
performing a strip process to strip the patterned photoresist protective layer off the patterned circuit layer; and
performing a chemical plating process on the patterned circuit layer to form a thickness-increased circuit layer thereat.

2. The method of manufacturing 3D circuit as claimed in claim 1, wherein the main body is for a 3D structure selected from the group consisting of an antenna, an LED carrier, a circuit substrate, a connector, an electronic device and a steering wheel.

3. The method of manufacturing 3D circuit as claimed in claim 1, wherein the main body is formed in a manner selected from the group consisting of injection molding and thermal sintering.

4. The method of manufacturing 3D circuit as claimed in claim 1, wherein the main body is made of a material selected from the group consisting of a polymeric material and a ceramic material.

5. The method of manufacturing 3D circuit as claimed in claim 4, wherein the polymeric material is selected from the group consisting of polyethylene (PE), polystyrene (PS), polycarbonate (PC), acrylonitrile-butadiene-styrene (ABS), polyethylene terephthalate (PET), poly(butylenes terephthalate) (PBT), liquid crystal polymer (LCP), polyamide (PA6/6T), nylon, polyoxymethylene (POM), and any composites thereof; and the ceramic material is selected from the group consisting of aluminum oxide, zirconium dioxide, silicon nitride, silicon carbide, barium titanate, and any composites thereof.

6. The method of manufacturing 3D circuit as claimed in claim 1, wherein, in the metallization process, any one of sputtering and evaporation is used to deposit a metal material on the surfaces of the main body to form the thin metal film; and the metal material for depositing on the main body is selected from the group consisting of nickel (Ni), cobalt (Co), palladium (Pd), Tin (Si), copper (Cu) and any composites thereof.

7. The method of manufacturing 3D circuit as claimed in claim 1, wherein the metallization process includes sensitization using stannous ions and activation using palladium ions to activate the surfaces of the main body to form the thin metal film.

8. The method of manufacturing 3D circuit as claimed in claim 1, wherein the photoresist coating process includes any one of dip coating and spray coating of a liquid photoresist to form the photoresist protective layer on the surface of the thin metal film; and the liquid photoresist for forming the photoresist protective layer being selected from the group consisting of a positive photoresist and a negative photoresist.

9. The method of manufacturing 3D circuit as claimed in claim 1, wherein, in the exposure and development process, any one of a laser light source and an ultraviolet (UV) light source is directly irradiated on areas or positions of the photoresist protective layer defined by a specific 3D exposure circuit pattern; and the 3D exposure circuit pattern being selected from the group consisting of a 3D patterned mask and a directly scanned pattern.

10. The method of manufacturing 3D circuit as claimed in claim 1, wherein, in the chemical plating process, a metal material selected from the group consisting of nickel (Ni), copper (Cu), gold (Au), silver (Ag), tin (Sn), chromium (Cr) and any composites thereof is used.

11. A method of manufacturing 3D circuit, comprising the following steps:
providing a main body of a 3D structure;
performing a surface pretreatment on surfaces of the main body;
performing a photoresist coating process to form a photoresist protective layer on the pretreated surfaces of the main body;
performing an exposure and development process to remove part of the photoresist protective layer and form a patterned photoresist protective layer at the remained photoresist protective layer;
performing a metallization process to form a patterned circuit zone on the surfaces of the main body at areas not covered by the patterned photoresist protective layer;
performing a strip process to strip the patterned photoresist protective layer off the main body; and
performing a chemical plating process on the patterned circuit zone to form a thickness-increased circuit layer thereat.

12. The method of manufacturing 3D circuit as claimed in claim 11, wherein the main body is for a 3D structure selected from the group consisting of an antenna, an LED carrier, a circuit substrate, a connector, an electronic device and a steering wheel.

13. The method of manufacturing 3D circuit as claimed in claim 11, wherein the main body is formed in a manner selected from the group consisting of injection molding and thermal sintering.

14. The method of manufacturing 3D circuit as claimed in claim 11, wherein the main body is made of a material selected from the group consisting of a polymeric material and a ceramic material.

15. The method of manufacturing 3D circuit as claimed in claim 14, wherein the polymeric material is selected from the group consisting of polyethylene (PE), polystyrene (PS), polycarbonate (PC), acrylonitrile-butadiene-styrene (ABS), polyethylene terephthalate (PET), poly(butylenes terephthalate) (PBT), liquid crystal polymer (LCP), polyamide (PA6/6T), nylon, polyoxymethylene (POM), and any composites thereof; and the ceramic material is selected from the group consisting of aluminum oxide, zirconium dioxide, silicon nitride, silicon carbide, barium titanate, and any composites thereof.

16. The method of manufacturing 3D circuit as claimed in claim 11, wherein the photoresist coating process includes any one of dip coating and spray coating of a liquid photoresist to form the photoresist protective layer on the surfaces of the main body; and the liquid photoresist for forming the photoresist protective layer being selected from the group consisting of a positive photoresist and a negative photoresist.

17. The method of manufacturing 3D circuit as claimed in claim 11, wherein, in the exposure and development process, any one of a laser light source and an ultraviolet (UV) light source is directly irradiated on areas or positions of the photoresist protective layer defined by a specific 3D exposure circuit pattern;
and the 3D exposure circuit pattern being selected from the group consisting of a 3D patterned mask and a directly scanned pattern.

18. The method of manufacturing 3D circuit as claimed in claim 11, wherein, in the metallization process, any one of sputtering and evaporation is used to deposit a metal material on the surfaces of the main body to form the patterned circuit zone; and the metal material for depositing on the main body is selected from the group consisting of nickel (Ni), cobalt (Co), palladium (Pd), Tin (Si), copper (Cu) and any composites thereof.

19. The method of manufacturing 3D circuit as claimed in claim 11, wherein the metallization process includes sensitization using stannous ions and activation using palladium ions to activate the surfaces of the main body to form the patterned circuit zone.

20. The method of manufacturing 3D circuit as claimed in claim 11, wherein, in the chemical plating process, a metal material selected from the group consisting of nickel (Ni), copper (Cu), gold (Au), silver (Ag), tin (Sn), chromium (Cr) and any composites thereof is used.
